(19) United States
(12) Patent Application Publication
(10) Pub. No.: US 2026/0115931 A1
(43) Pub. Date: Apr. 30, 2026

(54) TRANSFER ROBOT AND SUBSTRATE PROCESSING METHOD

(71) Applicant: SEMES CO., LTD., Cheonan-si (KR)

(72) Inventors: Doo Hyun BAEK, Hwaseong-si (KR); Ki Won HAN, Anseong-si (KR); Hee Chan KIM, Hwaseong-si (KR); Sang Oh KIM, Seoul (KR)

(73) Assignee: SEMES CO., LTD., Cheonan-si (KR)

(21) Appl. No.: 19/373,170

(22) Filed: Oct. 29, 2025

(30) Foreign Application Priority Data
Oct. 30, 2024 (KR) 10-2024-0151160

(51) Int. Cl. B25J 11/00; B25J 9/10; B25J 15/06; H01L 21/677

(52) U.S. Cl. CPC B25J 11/0095; B25J 9/104; B25J 15/0616; H10P 72/3302

(57) ABSTRACT

Provided is a transfer robot for transferring a substrate, the transfer robot including: a hand for supporting a substrate; and a driving unit for driving the hand, in which the hand includes: a base plate; a first support part mounted on the base plate and vacuum-adsorbing a bottom surface of the substrate and supporting the substrate; and a second support part mounted on the base plate and supporting an edge region of the substrate, and the first support part and the second support part are configured to support the substrate at different heights.

### CROSS-REFERENCE TO RELATED APPLICATION

This application claims priority to and the benefit of Korean Patent Application No. 10-2024-0151160 filed in the Korean Intellectual Property Office on Oct. 30, 2024, the entire contents of which are incorporated herein by reference.

### TECHNICAL FIELD

The present invention relates to a transfer robot and a substrate processing method, and more specifically, to a transfer robot that transfers a substrate and a method of processing a substrate using the same.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate. Since the pre-treated substrate before the cleaning process contains contaminants, such as particles and fumes, there is a problem of reverse contamination of the hand when the contaminated (dirty) substrate before processing and the clean substrate after the cleaning process are transferred using the same hand. Accordingly, a method of transferring the substrate before processing and the substrate after the cleaning process using different hands is known.

However, when the substrate is transferred using different hands, there is a problem that the size of the transfer robot increases and the process efficiency decreases.

### SUMMARY OF THE INVENTION

The present invention has been made in an effort to provide a transfer robot capable of efficiently processing a substrate and a substrate processing method using the same.

The present invention has also been made in an effort to provide a transfer robot that simplifies the configuration and a substrate processing method using the same.

The present invention has also been made in an effort to provide a transfer robot capable of transferring an unprocessed substrate and a processed substrate through different support parts of one hand, and a substrate processing method using the same.

The objectives of the present disclosure are not limited thereto and other objectives not stated herein may be clearly understood by those skilled in the art from the following description.

An exemplary embodiment of the present disclosure, a transfer robot for transferring a substrate, the transfer robot comprising: a hand for supporting a substrate; and a driving unit for driving the hand, wherein the hand includes: a base plate; a first support part mounted on the base plate and vacuum-adsorbing a bottom surface of the substrate and supporting the substrate; and a second support part mounted on the base plate and supporting an edge region of the substrate, and the first support part and the second support part may be configured to support the substrate at different heights.

According to the exemplary embodiment of the present invention, wherein the second support part may includes: a first support and a second support that support a side end of the substrate and are arranged to face each other with the first support part interposed therebetween when viewed from above; and a driving unit for moving the first support and the second support in a direction of getting closer to each other or in a direction away from each other.

According to the exemplary embodiment of the present invention, wherein the driving unit moves the first support and the second support between a first position and a second position, the first position is a position where the first support and the second support support the substrate, and when viewed from above, the second position may be a position where the first support and the second support are spaced apart from the substrate supported by the first support part.

According to the exemplary embodiment of the present invention, wherein the first support and the second support include guide members provided on upper surfaces of the first support and the second support, respectively, and the guide member supports a side end portion of the substrate and simultaneously may guides a side surface of the substrate when the substrate is supported by the second support part.

According to the exemplary embodiment of the present invention, wherein the guide members are provided at front ends and rear ends of the first support and the second support, respectively, and may be arranged to surround the substrate when the substrate is supported by the first support part.

According to the exemplary embodiment of the present invention, wherein the driving unit includes: a driving pulley rotated by a motor; a driven pulley; and a belt provided to surround the driving pulley and the driven pulley, and the first support and the second support may be coupled to the belt.

According to the exemplary embodiment of the present invention, the transfer robot may further include a base, wherein the hand may be provided so as to be movable forward and backward with respect to the base.

According to the exemplary embodiment of the present invention, wherein the first support part includes: a connection part connected to the base plate; and a first finger and a second finger extending from the connection part, and each of the first finger, the second finger, and the connection part may be provided with a vacuum pad that vacuum-adsorbs the substrate.

According to the exemplary embodiment of the present invention, wherein a plurality of hands is provided, and the plurality of hands may be provided to be spaced apart from each other in a vertical direction.

According to the exemplary embodiment of the present invention, wherein the second support part includes: a fixed guide member provided on an upper surface of the first finger and an upper surface of the second finger; a driving guide member provided on an upper surface of the connection part; and a driving unit for moving the driving guide member, and the fixed guide member and the driving guide member support a side end portion of the substrate and may guide a side surface of the substrate when the substrate is supported by the second support part.

According to the exemplary embodiment of the present invention, wherein the driving unit moves the driving guide member between a first position and a second position, the first position is a position where the driving guide member supports the substrate when the second support part supports the substrate, and the second position may be a position of the driving guide member when the second support part does not support the substrate.

According to the exemplary embodiment of the present invention, wherein when viewed from above, a center position of the substrate when the first support part supports the substrate may be provided differently from a center position of the substrate when the second support part supports the substrate.

An exemplary embodiment of the present disclosure, a method of processing a substrate, the method comprising: transferring a substrate using a hand having a first support part that vacuum-adsorbs and supports the substrate and a second support part that grips and supports the substrate, wherein when the substrate is loaded into a chamber and the substrate is unloaded from the chamber, the substrate may be supported and transferred by different support parts.

According to the exemplary embodiment of the present invention, wherein when the substrate is loaded into the chamber, the substrate is supported and transferred while being vacuum-adsorbed, and when the substrate is unloaded from the chamber, the substrate may be supported and transferred while being gripped.

According to the exemplary embodiment of the present invention, wherein the first support part and the second support part may support the substrate at different heights.

According to the exemplary embodiment of the present invention, wherein the chamber may be a liquid treating chamber that supplies a treatment liquid to the substrate and liquid-treats the substrate.

According to the exemplary embodiment of the present invention, wherein the chamber may be a buffer chamber for temporarily storing the substrate.

According to the exemplary embodiment of the present invention, wherein when the substrate is supported by any one of the first support part and the second support part, the substrate may be not in contact with the other of the first support part and the second support part.

An exemplary embodiment of the present disclosure, a transfer robot for transferring a substrate, the transfer robot comprising: a hand for supporting a substrate; and a driving unit for driving the hand, wherein the hand includes: a base plate; a first support part mounted on the base plate and vacuum-adsorbing a bottom surface of the substrate and supporting the substrate; and a second support part mounted on the base plate and supporting an edge region of the substrate, and the first support part includes: a connection part connected to the base plate; and a first finger and a second finger extending from the connection part, and each of the first finger, the second finger, and the connection part is provided with a vacuum pad that vacuum-adsorbs the substrate, the second support part includes: a first support and a second support that support a side end of the substrate and are arranged to face each other with the first support part interposed therebetween when viewed from above; and a driving unit for moving the first support and the second support in a direction of getting closer to each other or in a direction away from each other, the first support and the second support include guide members provided on upper surfaces of the first support and the second support, respectively, and the guide member supports a side end portion of the substrate and simultaneously guides a side surface of the substrate when the substrate is supported by the second support part, and the first support part and the second support part may be configured to support the substrate at different heights.

According to the exemplary embodiment of the present invention, the transfer robot may further include a base, wherein a plurality of hands is provided, the plurality of hands is provided on an upper portion of the base to be spaced apart from each other in a vertical direction, and each of the plurality of hands may be provided so as to be movable forward and backward with respect to the base.

According to the exemplary embodiment of the present invention, it is possible to efficiently process a substrate.

Further, according to the exemplary embodiment of the present invention, it is possible to simplify the configuration.

Further, according to the exemplary embodiment of the present invention, it is possible to transfer an unprocessed substrate and a processed substrate through different support parts of one hand.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a diagram schematically illustrating a liquid treating chamber of FIG. 1 according to an exemplary embodiment.

FIG. 3 is a perspective view illustrating a hand of FIG. 2 according to an exemplary embodiment of the present invention, FIG. 4 is a plan view of the hand of FIG. 3, and FIG. 5 is a side view of the hand of FIG. 3.

FIG. 6 is a diagram schematically illustrating a liquid treating chamber provided as a process chamber of FIG. 1 according to an exemplary embodiment.

FIG. 7 is a flowchart of a substrate processing method of the present invention.

FIGS. 8 and 9 illustrate a state in which the hand of FIG. 3 supports a substrate in an operation of loading an unprocessed substrate of FIG. 7 into a chamber.

FIGS. 10 and 11 illustrate a state in which the hand of FIG. 3 supports the substrate in an operation of unloading the processed substrate of FIG. 7 from the chamber.

FIGS. 12 to 16 illustrate a hand according to another exemplary embodiment of the present invention.

FIGS. 17 to 18 illustrate a hand according to another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on the process in which a substrate W is liquid-treated by supplying a liquid, such as a cleaning liquid, onto the substrate W as an example. However, the present exemplary embodiment is not limited to the cleaning process, and may be applied to various processes of processing the substrate W using a liquid, such as an etching process, an ashing process, or a developing process.

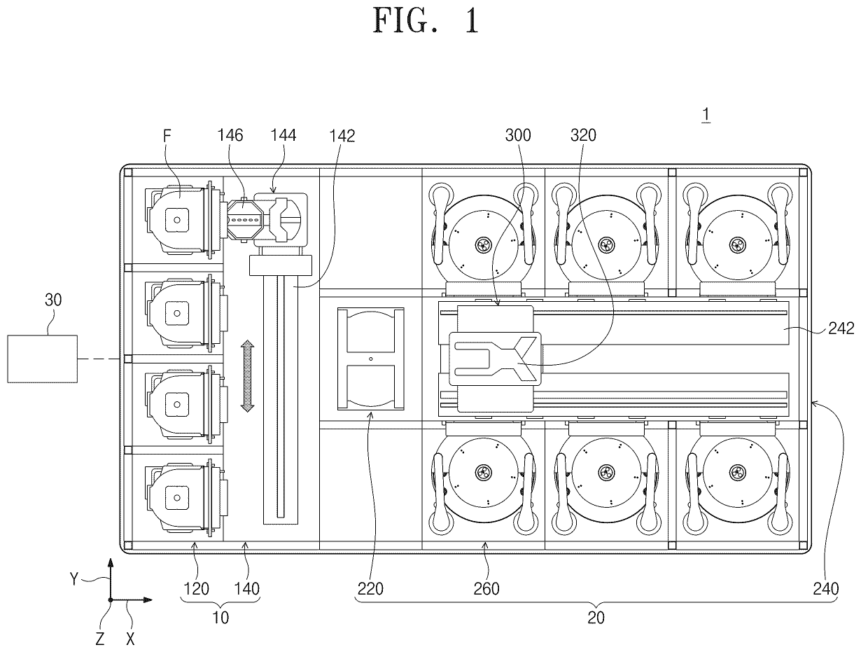

Hereinafter, an exemplary embodiment of the present invention will be described in detail with reference to FIGS. 1 to 16. A substrate processing apparatus 1 according to an exemplary embodiment of the present invention may perform a cleaning process including a drying process of drying a substrate W using a process fluid.

FIG. 1 is a plan view schematically illustrating a substrate processing apparatus according to an exemplary embodiment of the present invention. Referring to FIG. 1, a substrate processing apparatus 1 includes an index module 10, a treating module 20, and a controller 30. According to an exemplary embodiment, the index module 10 and the treating module 20 are disposed along one direction. Hereinafter, a direction in which the index module 10 and the treating module 20 are arranged is defined as a first direction X. When viewed from above, a direction perpendicular to the first direction X is defined as a second direction Y, and a direction perpendicular to the plane including both the first direction X and the second direction Y is defined as a third direction Z.

The index unit 10 transfers the substrate W from a container F in which the substrate W is accommodated to the treating unit 20 for treating the substrate W. The index module 10 accommodates the substrate W completely processed in the treating module 20 into the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction Y. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction Y in its longitudinal direction. The index robot 144 may transfer the substrate W. The index robot 144 may transfer the substrate W between the index module 10 and a buffer chamber 220 to be described later.

The index robot 144 includes an index hand 146. The substrate W is seated on the index hand 146. The index hand 146 may be provided on the index rail 142 to be movable along the second direction Y. Accordingly, the transfer hand 146 may be moved forward and backward along the guide rail 142. Also, the index hand 146 may be provided to be rotatable with respect to the third direction Z. Also, the index hand 146 may be provided to be vertically movable along the third direction Z. A plurality of index hands 146 may be provided. A plurality of transfer hands 146 may be provided to be spaced apart from each other in the vertical direction. A plurality of transfer hands 146 may move forward, backward, and rotate independently of each other.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to a process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform the substrate processing method described below. For example, the controller 30 may control the configurations provided to the transfer robot 300 and the process chamber 260 so as to perform a substrate processing method described below.

The treating module 20 includes a buffer chamber 220, a transfer frame 240, and a process chamber 260. The buffer chamber 220 provides a space in which the substrate W loaded into the treating module 20 and the substrate W unloaded from the treating module 20 stay temporarily. The transfer frame 240 provides a transfer space for transferring the substrate W between the buffer chamber 220 and the process chamber 260.

The buffer chamber 220 may be disposed between the index frame 140 and the transfer chamber 240. The buffer chamber 220 may be located at one end of the transfer frame 240. A slot (not illustrated) in which the substrate W is placed is provided in the buffer chamber 220. A plurality of slots (not illustrated) is provided. A plurality of slots (not illustrated) is provided to be spaced apart from each other along the third direction Z. A front face and a rear face of the buffer chamber 220 are opened. The front face is a face facing the index module 10, and the rear face is a face facing the transfer frame 240. The index robot 144 may approach the buffer chamber 220 through the front face, and the transfer robot 300 may approach the buffer chamber 220 through the rear face.

The transfer frame 240 may be provided so that a longitudinal direction is the first direction X. The process chambers 260 may be disposed on opposite sides of the transfer frame 240. The process chamber 260 may be disposed on a side portion of the transfer frame 240. The transfer frame 240 and the process chamber 260 may be disposed along the second direction Y.

According to the example, the treating chambers 260 are disposed on opposite sides of the transfer frame 240. At one side of the transfer frame 240, the process chambers 260 may be provided in an array of A×B (each of A and B is 1 or a natural number larger than 1) in the first direction X and the third direction Z. Herein, A is the number of process chambers 260 provided in a row along the first direction X, and B is the number of process chambers 260 provided in a row along the third direction Z. For example, when six process chambers 260 are provided at one side of the transfer frame 240, the process chambers 260 may be arranged in a 3×2 array. The number of process chambers 260 may increase or decrease. Unlike the above description, the process chamber 260 may be provided as a single layer on one side and opposite sides of the transfer frame 240.

The transfer frame 240 includes a guide rail 242 and a transfer robot 300. The guide rail 242 is provided within the transfer frame 240 in the first direction X in a longitudinal direction thereof. The transfer robot 300 may be provided on the guide rail 242 to be able to move linearly along the first direction X. The transfer robot 300 transfers the substrate W between the buffer chamber 220 and the process chamber 260.

The process chamber 260 may process the substrate W. For example, the process chamber 260 may be a chamber for performing a cleaning process for removing process by-products or the like attached to the substrate W. For example, the process chamber 260 may be provided as the liquid treating chamber 400 to perform a liquid treatment process of liquid-treating the substrate W by supplying a liquid onto the substrate W. Hereinafter, the present invention will be described based on the case where the process chamber 260 is the li quid treating chamber 400 as an example. The liquid treating chamber 400 may process the substrate W by supplying a chemical, a rinse liquid, and/or an organic solvent onto the substrate W. The processing of the substrate W performed in the liquid treating chamber 400 may include a spin drying treatment in which the liquid remaining on the substrate W is removed by rotating the substrate W.

The process chamber 260 may have different structures depending on the type of process for processing the substrate W. Each of the process chambers 260 may have the same structure.

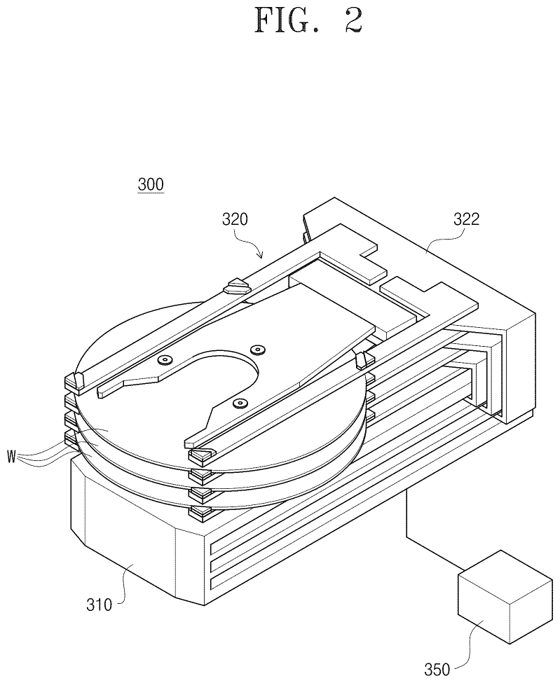

FIG. 2 is a perspective view illustrating the transfer robot according to a first exemplary embodiment of the present invention. Referring to FIG. 2, the transfer robot 300 includes a base 310, a hand 320, and a driving unit 350. The base 310 is installed to be movable along the guide rail 242. The base 310 supports the hand 320. The hand 320 is connected with the base 310.

The substrate W is placed on the hand 320. A plurality of hands 320 may be provided by being stacked on the base 310. The hand 320 is provided to be able to move forward and backward with respect to the base 310. The hand 320 directly loads or unloads the substrate W into or from the process chamber 260 through an entrance. A plurality of transfer hands 320 may be provided to be spaced apart from each other in the vertical direction. A plurality of transfer hands 320 may move forward and backward, and rotate independently of each other by the driving unit 350 described later. Although FIG. 2 illustrates that the transfer robot 300 includes four hands 320, the number of the hands 320 may increase or decrease according to the process efficiency of the substrate processing apparatus 1.

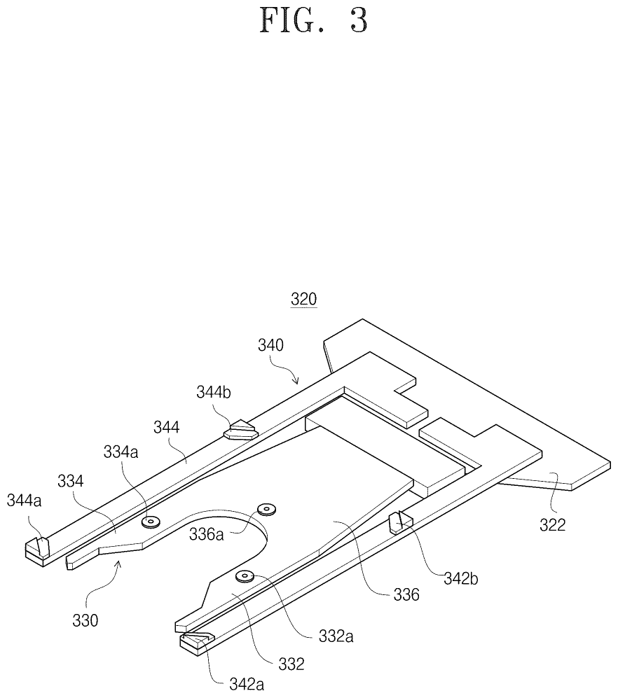

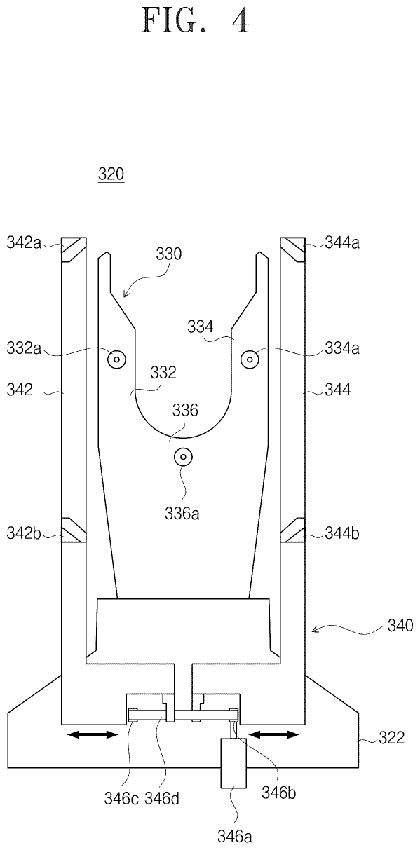

FIG. 3 is a perspective view illustrating the hand of FIG. 2 according to the exemplary embodiment of the present invention, FIG. 4 is a plan view of the hand of FIG. 3. FIG. 5 is a side view of the hand of FIG. 3.

Hereinafter, the hand 320 according to a first exemplary embodiment of the present invention will be described in detail with reference to FIGS. 3 to 5.

The hand 320 includes a base plate 322, a first support part 330, a second support part 340, and a driving unit 350. The base plate 322 is connected to the base 310. The first support part 330 may support and support the bottom surface of the substrate W by vacuum adsorption. The first support part 330 may support a first region of the substrate W and transfer the substrate W. The first support part 330 may include a first finger 332, a second finger 334, a connection part 336, and vacuum pads 332a, 334a, and 336a.

The first fingerer 332 and the second fingerer 334 have a rod shape, are positioned to face each other while being spaced apart from each other, and are provided to extend in the same direction from the connection part 336. Both sides of a front end of the connection part 336 are connected to the first fingerer 332 and the second fingerer 334, respectively, and a base end of the connection part 336 is connected to the base plate 322. The base end of the connection part 336 may be fixedly installed on the base plate 322.

The first fingerer 332, the second fingerer 334, and the connection part 336 may include vacuum pads 332a, 334a, and 336a that vacuum-adsorb a substrate, respectively. The vacuum pad may include a first vacuum pad 332a formed in the first fingerer 332, a second vacuum pad 334a formed in the second fingerer 334, and a third vacuum pad 336a formed in the connection part 336.

Although not illustrated, each of the vacuum pads 332a, 334a, and 336a includes configurations capable of vacuum-adsorbing a bottom surface of the substrate W. For example, a vacuum flow path is formed in the first fingerer 332, the second fingerer 334, the connection part 336, and the base plate 322, and the vacuum flow path (not illustrated) is connected to a vacuum pressure supply unit through a vacuum line (not illustrated). The vacuum pressure supply unit may supply a vacuum pressure to the vacuum pads 332a, 334a, and 336a so that the vacuum pads 332a, 334a, and 336a absorb a bottom surface of the substrate W. Vacuum holes are formed in the vacuum pads 332a, 334a, and 336a, and the first support part 330 forms a vacuum pressure through the vacuum holes formed in the vacuum pads 332a, 334a, and 336a to adsorb the substrate W placed on the first support part 330.

The second support part 340 may support a second region of the substrate W and transfer the substrate W. The second region may be a region farther from the center of the substrate W than the first region of the substrate W supported by the first support part 330. The second region may be an edge region of the substrate W. In other words, the second support part 340 may support a side end region of the substrate W.

The second support part 340 includes a first support 342, a second support 344, a driving unit 346, and guide members 342a, 342b, 344a and 344b.

Each of the first support 342 and the second support 344 is disposed on the base plate 322. The first support 342 and the second support 344 face each other while being spaced apart from each other, and are provided to extend from the base plate 322 in the same direction. When viewed from above, the first support 342 and the second support 344 are disposed to face each other with the first support part 330 interposed therebetween. The heights of the upper surfaces of the first support 342 and the second support 344, and the heights of the upper surfaces of the first support part 332, the second finger 334, and the connection part 336 of the first support part 330 may be provided as the same height.

The first support 342 and the second support 344 extend in the forward direction of the base plate 322, that is, in the front end direction of the base plate 322. The first support 342 and the second support 344 may be provided in, for example, a rod shape. However, the present invention is not limited thereto, and may be changed into various shapes capable of supporting the substrate W.

Guide members 342a and 342b may be provided at a front end and a rear end of the first support 342, respectively. The guide members 342a and 342b may protrude from a top surface of the first support 342. The substrate W may be seated on the guide members 342a and 342b. The guide members 342a and 342b may be stepped, and may be provided to guide a side surface of the substrate W when the substrate W is seated on the guide members 342a and 342b. Guide members 344a and 344b may be provided at a front end and a rear end of the second support 344, respectively. Since the guide members 344a and 344b provided on the second support 344 have the same configuration as the guide members 342a and 342b provided on the first support 342, detailed descriptions thereof will be omitted.

The guide members 342a, 342b, 344a, and 344b are aligned with the second support part 340 and disposed to surround the supported substrate.

The driving unit 346 is connected to the first support 342 and the second support 344, and moves the first support 342 and the second support 344. The driving unit 346 may move the first support 342 and the second support 344 in a direction of becoming closer to each other or in a direction of becoming farther away from each other. The driving unit 346 may move the first support 342 and the second support 344 between a first position and a second position. The first position is a position at which the first support 342 and the second support 344 support the substrate W, and the second position is a position at which the first support 342 and the second support 344 do not support the substrate W.

When the first support 342 and the second support 344 are in the first position, the distance between the first support 342 and the second support 344 may be closer than the distance between the first support 342 and the second support 344 when the first support 342 and the second support 344 are in the second position.

When the substrate W is adsorbed and supported by the first support part 330, the first support 342 and the second support 344 may be located at the second position. When the first support 342 and the second support 344 are located at the second position, the first support 342 and the second support 344 may be spaced apart from each other so as not to be in contact with the substrate W adsorbed and supported by the first support part 330.

The driving unit 346 may be provided, for example, as a belt pulley including a motor 346a, a driving pulley 346b, a driven pulley 346c, and a belt 346d. The driving pulley 346b is rotated by the motor 346a, and the belt 346d provided to surround the driving pulley 346b and the driven pulley 346c is rotated by rotation of the driving pulley 346b, and the first support 342 and the second support 344 may be coupled to the belt 346d to move in a direction closer to each other or away from each other according to the rotation direction of the belt 346d.

The driving unit 350 may allow the hand 320 to move forward and backward with respect to the base 310. The driving unit 350 may include a horizontal driving unit and a vertical driving unit, which are not illustrated, and may rotate the base 310 with respect to the third direction Z as an axis or move the base 310 in a vertical direction along the third direction Z.

The first support part 330 and the second support part 340 are configured to support the substrate W at different heights. As illustrated in FIG. 4, a height at which the vacuum pads 332a, 334a, and 336a protrude from the first support part 330 is lower than a height at which the guide members 342a, 342b, 344a, and 344b protrude from the second support part 340. Accordingly, a height of the substrate W when the substrate W is supported by the first support part 330 is lower than a height of the substrate W when the substrate W is supported by the second support part 340. When the substrate W is supported by the first support part 330, the substrate W is not in contact with the second support part 340, and when the substrate W is supported by the second support part 340, the substrate W is not in contact with the first support part 330. When the substrate W is supported by any one of the first support part 330 and the second support part 340, the other support part is provided not to be in contact with the substrate W, and thus contamination of the support part through the substrate W may be prevented. Details thereof will be described later.

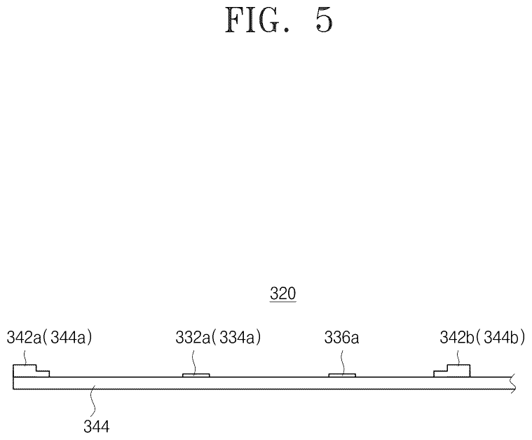

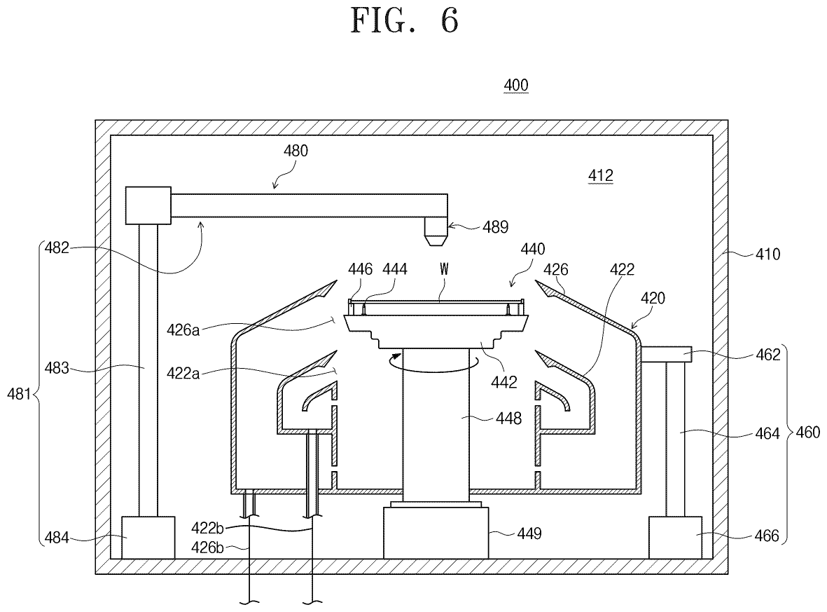

FIG. 6 is a diagram schematically illustrating the liquid treating chamber provided as the process chamber of FIG. 1 according to an exemplary embodiment. Referring to FIG. 6, the liquid treating chamber 400 includes a housing 410, a cup 420, a support unit 440, a lifting unit 460, and a liquid supply unit 480.

The housing 410 has a processing space 412 therein. The housing 410 may have a cylindrical shape having a space therein. The cup 420, the support unit 440, the lifting unit 460, the liquid supply unit 480 may be provided in the processing space 412 of the housing 410. The housing 410 may have a rectangular shape when viewed in a front cross-sectional view. However, the present invention is not limited thereto, and the housing 410 may be modified into various shapes which may have the processing space 412. An opening (not illustrated) is formed at one side of the housing 410. The opening (not illustrated) functions as an entrance through which the substrate W is loaded in or unloaded from the inner space of the housing 410 by the transfer robot 300.

The cup 420 has a cylindrical shape with an open top. The cup 420 has an internal recovery container 422 and an external recovery container 426. The recovery containers 422 and 426 recover different treatment liquids among treatment liquids used in the process. The internal recovery container 422 is provided in an annular ring shape surrounding the substrate W and the support unit 440, and the external recovery container 426 is provided in an annular ring shape surrounding the internal recovery container 422. An inner space 422a of the internal recovery container 422 and the internal recovery container 422 function as a first inlet 422a through which the treatment liquid is introduced into the internal recovery container 422. The space 426a between the internal recovery container 422 and the external recovery container 426 functions as a second inlet 426a through which the treatment liquid is introduced into the external recovery container 426. According to an example, the respective inlets 422a and 426a may be positioned at different heights. Recovery lines 422b and 426b are connected below the bottom surfaces of the recovery containers 422 and 426, respectively. The treatment liquids introduced into the recovery containers 422 and 426 may be provided to an external treatment liquid regeneration system (not illustrated) through the recovery lines 422b and 426b, respectively, and may be reused.

The support unit 440 supports the substrate W in the processing space 412. The supporting unit 440 supports and rotates the substrate W during the process. The support unit 440 includes a support plate 442, a support pin 444, a chuck pin 446, and rotation driving members 448 and 449.

The support plate 442 is provided in a generally circular plate shape, and has an upper surface and a lower surface. The lower surface has a smaller diameter than the upper surface. That is, the support plate 442 may have a shape having a wide upper surface and a narrow lower surface. The upper and lower surfaces are positioned so that their central axes coincide with each other. Furthermore, the support plate 442 may be provided with a heating means (not illustrated). The heating means provided to the support plate 442 may heat the substrate W placed on the support plate 442. The heating means may generate heat. The heat generated by the heating means may be heat or cold heat. The heat generated by the heating means may be transferred to the substrate W placed on the support plate 442. In addition, the heat transferred to the substrate W may heat the treatment liquid supplied to the substrate W. The heating means may be a heater and/or a cooling coil. However, the present invention is not limited thereto, and the heating means may be variously modified into a known device.

A plurality of support pins 444 is provided. The support pins 444 are disposed on the edge of the upper surface of the support plate 442 while being spaced apart at a predetermined interval and protrude upward from the support plate 442. The support pins 444 are arranged to have an annular ring shape as a whole by combination with each other. The support pin 444 supports the rear edge of the substrate W so that the substrate W is spaced apart from the upper surface of the support plate 442 by a predetermined distance.

A plurality of chuck pins 446 is provided. The chuck pin 446 is disposed to be farther from the center of the support plate 442 than the support pin 444. The chuck pin 446 is provided to protrude upward from the upper surface of the support plate 442. The chuck pin 446 supports a side portion of the substrate W so that the substrate W is not separated from a regular position in a lateral direction when the support plate 442 is rotated. The chuck pin 446 is provided to be linearly moved between an outer position and an inner position along a radial direction of the support plate 442. The outer position is a position farther from the center of the support plate 442 than the inner position. The outer position is defined as the position of the chuck pin 446 when the substrate W is received from the transfer robot 300 or when the substrate W is handed over to the transfer robot 300. When the substrate W is loaded on or unloaded from the support plate 442, the chuck pin 446 is positioned at the outer position, and the chuck pin 446 is positioned at the inner position when the process is performed on the substrate W. The inner position is a position where the chuck pin 446 and the side portion of the substrate W are in contact with each other, and the outer position is a position where the chuck pin 446 and the substrate W are spaced apart from each other.

The rotation driving members 448 and 449 rotate the support plate 442. The support plate 442 is rotatable with respect to a magnetic central axis by the rotation driving members 448 and 449. The rotation driving members 448 and 449 include a support shaft 448 and a driving unit 449. The support shaft 448 has a cylindrical shape. An upper end of the support shaft 448 is fixedly coupled to a bottom surface of the support plate 442. According to an example, the support shaft 448 may be fixedly coupled to a center of a bottom surface of the support plate 442. The driving unit 449 provides driving force to rotate the support shaft 448. The support shaft 448 is rotated by the driving unit 449, and the support plate 442 is rotatable together with the support shaft 448.

The lifting unit 460 linearly moves the cup 420 in the up and down direction. As the cup 420 is moved up and down, a relative height of the cup 420 with respect to the support plate 442 is changed. When the substrate W is loaded onto the support plate 442 or unloaded, the lifting unit 460 lowers the cup 420 such that the support plate 442 protrudes upward from the cup 420. Also, when the process is performed, the height of the cup 420 is adjusted so that the treatment liquid may be introduced into the preset recovery containers 422 and 426 according to the type of treatment liquid supplied to the substrate W. The lifting unit 460 includes a bracket 462, a moving shaft 464, and a driver 466. The bracket 462 is fixedly installed on the outer wall of the cup 420, and the moving shaft 464 that moves in the up and down direction by the driver 466 is fixedly coupled to the bracket 462. Selectively, the lifting unit 460 may move the support plate 442 in the up and down direction.

The liquid supply unit 480 may supply a treatment liquid to the substrate W. The treatment liquid may be an organic solvent, the chemical or rinse liquid. The organic solvent may be an isopropyl alcohol (IPA) liquid.

The liquid supply unit 480 may include a moving member 481 and a nozzle 489. The moving member 481 moves the nozzle 489 to a process position and a standby position. The process position is a position at which the nozzle 489 faces the substrate W supported by the support unit 440. According to an example, the process position is a position at which the treatment liquid is discharged onto the upper surface of the substrate W. In addition, the process position includes a first supply position and a second supply position. The first supply position may be a position closer to the center of the substrate W than the second supply position, and the second supply position may be a position including the end of the substrate W. Optionally, the second supply position may be a region adjacent to the end of the substrate W. The standby position is defined as a position at which the nozzle 489 is out of the process position. According to an example, the standby position may be a position at which the nozzle 489 waits before or after the process is processed on the substrate W.

The moving member 481 includes an arm 482, a support shaft 483, and a driver 484. The support shaft 483 may be positioned at one side of the cup 420. The support shaft 483 has a rod shape of which a longitudinal direction thereof faces a fourth direction. The support shaft 483 is provided to be rotatable by the driver 484. The support shaft 483 is provided to be movable in an up and down direction. The arm 482 is coupled to an upper end of the support shaft 483. The arm 482 vertically extends from the driver 484. The nozzle 489 is coupled to an end of the arm 482. As the support shaft 483 is rotated, the nozzle 489 may be swing-moved together with the arm 482. The nozzle 489 may be swing-moved to the process position and the standby position. Selectively, the arm 482 may be provided to be moved forward and backward toward a longitudinal direction thereof. When viewed from above, a path through which the nozzle 489 moves may coincide with a central axis of the substrate W at the process position.

Hereinafter, an exemplary embodiment of a method of processing a substrate using the substrate processing apparatus of FIG. 1 will be described. The substrate processing method described below may be performed by the substrate processing apparatus 1 including the index module 10, the buffer chamber 220, the process chamber 260, and the transfer robot 300. Further, the controller 300 may perform the substrate processing method described below by controlling the configurations of the substrate processing apparatus 1, such as the index module 10, the buffer chamber 220, the process chamber 260, and the transfer robot 300.

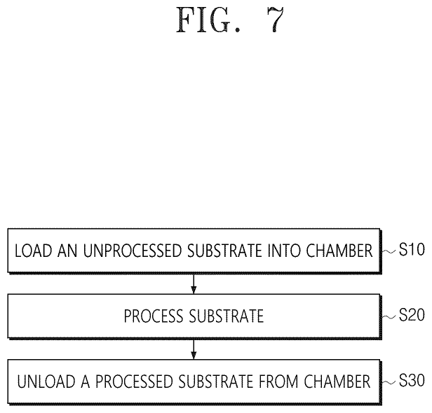

FIG. 7 is a flowchart of a substrate processing method of the present invention. Referring to FIG. 7, the substrate processing method according to the exemplary embodiment of the present invention includes loading an unprocessed substrate into a chamber (S10), processing the substrate in the chamber (S20), and unloading the processed substrate from the chamber (S30).

In the step S10 of loading the unprocessed substrate into the chamber, the transfer robot 300 loads the substrate W into the inner space of the liquid treating chamber 400. In this case, the substrate W may be vacuum-adsorbed by the first support part 330 to be transferred to the liquid treating chamber 400.

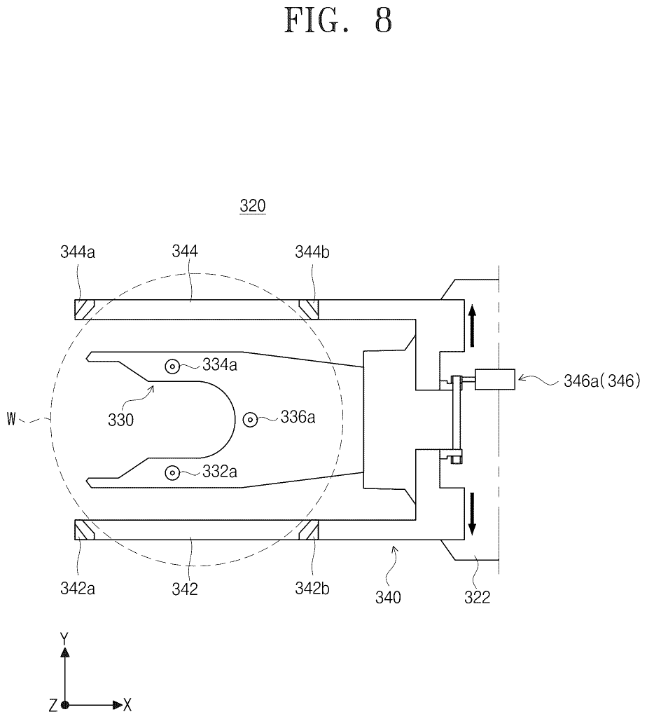

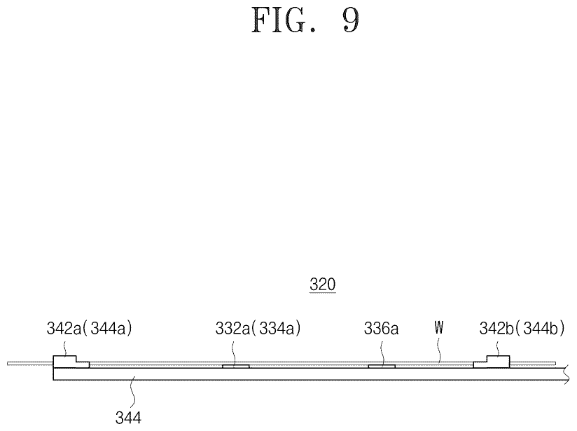

FIGS. 8 and 9 illustrate a state in which the hand of FIG. 3 supports a substrate in the operation of loading the unprocessed substrate of FIG. 7 into the chamber.

FIG. 8 is a front view illustrating the hand 320 of FIG. 3 in the step S10 of loading the unprocessed substrate into the chamber, and FIG. 9 is a side view of the hand 320 of FIG. 8.

Referring to FIGS. 8 and 9, in the step S10 of loading the unprocessed substrate into the chamber, the substrate W is adsorbed and supported by the first support part 330. When the substrate W is adsorbed and supported by the first support part 330, the driving unit 346 moves the first support 342 and the second support 344 to be positioned at the second position. The first support 342 and the second support 344 are spaced apart from each other so as not to be in contact with the substrate W adsorbed and supported by the first support part 330. As illustrated in FIG. 9, the bottom surface of the substrate W is adsorbed and supported by the vacuum pads 332a, 334a, and 336a, and the substrate W placed on the hand 320 is loaded into the liquid treating chamber 400. For example, the substrate W may be transferred from the buffer chamber 220 to the liquid treating chamber 400.

When the substrate W is loaded into the liquid treating chamber 400, the substrate is processed in the chamber S20.

The substrate W loaded into the liquid treating chamber 400 may be liquid-treated in a state of being supported by the support unit 440. The liquid supply unit 480 processes the substrate W by supplying the treatment liquid to the substrate W.

When the processing of the substrate W is completed in the liquid treating chamber, the step S30 of unloading the processed substrate from the chamber is performed.

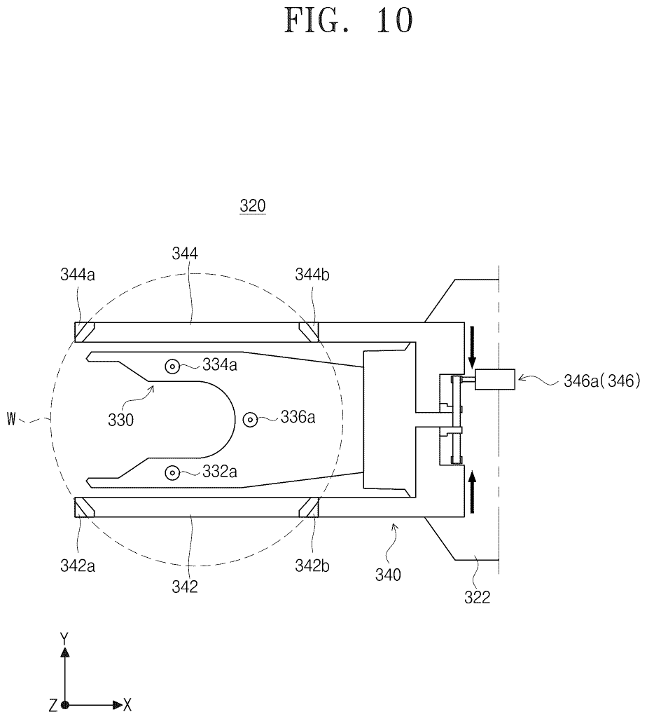

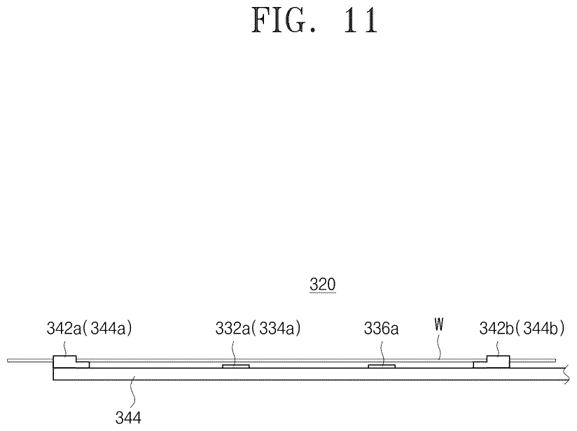

FIGS. 10 and 11 illustrate a state in which the hand of FIG. 3 supports the substrate in the operation of unloading the processed substrate of FIG. 7 from the chamber.

FIG. 10 is a front view illustrating the hand 320 of FIG. 3 in the step S10 of loading the processed substrate from the chamber, and FIG. 11 is a side view of the hand 320 of FIG. 10.

Referring to FIGS. 10 and 11, in the step S30 of unloading the substrate from the chamber, the substrate W is gripped and supported by the second support part 340. When the substrate W is gripped and supported by the second support part 340, the driving unit 346 moves the first support 342 and the second support 344 to be positioned at the first position. The first support 342 and the second support 344 move in a direction in which the first support 342 and the second support 344 are brought closer to each other by the driving unit 346, and the substrate W is seated on the guide members 342a, 342b, 344a and 344b provided on the first support 342 and the second support 344. As illustrated in FIG. 11, the edge region of the substrate W is gripped and supported by the guide members 342a, 342b, 344a, and 344b. That is, the guide members 342a, 342b, 344a, and 344b support the bottom surface of the side end portion of the substrate W and guide the side surface of the substrate so that the substrate W is fixed on the second support part 340 in a supported state. The substrate W placed on the hand 320 is unloaded from the liquid treating chamber 400. Thereafter, the transfer robot 300 may transfer the substrate W to the buffer chamber 220.

As the unprocessed substrate W is supported and transferred by a vacuum adsorption method, the substrate W may be fixed to the hand 320, thereby transferring the substrate at a faster speed than when the substrate W is gripped and transferred. Accordingly, the transfer speed and process processing efficiency of the substrate W may be increased.

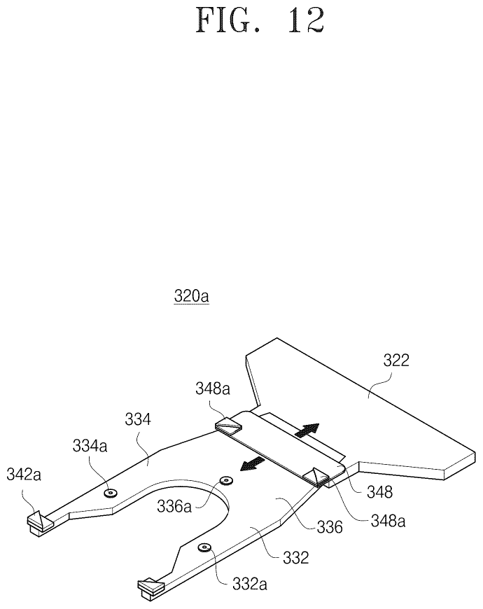

FIGS. 12 to 16 illustrate a hand according to another exemplary embodiment of the present invention.

Hereinafter, a hand 320a according to another exemplary embodiment of the present invention will be described with reference to FIGS. 12 to 16. A detailed description will be omitted by giving the same reference numerals to the same configuration as the hand 320 of FIG. 3, and a difference from the hand 320 of FIG. 3 will be mainly described. A second support part 340a of the hand 320a includes guide members 342a and 344a, a driving plate 348, and a driving guide member 348a.

Guide members 342a and 344a are provided on the upper surfaces of the first finger 332 and the second finger 334, a driving plate 348 is provided on the upper surface of the connection part 336, and a driving guide member 348a is provided on the upper surface of the driving plate 348a.

The guide members 342a and 344a are provided at the front ends of the first finger 332 and the second finger 334, are stepped as in the case of the hand 320 of FIG. 3, and are provided to guide the side of the substrate W when the substrate W is seated on the guide members 342a and 342b.

The driving plate 348 is provided to move forward or backward from the upper portion of the connection part 336 by a driving unit (not illustrated). The driving guide member 348a is fixedly installed on the driving plate 348. The driving guide member 348a is stepped, and is provided to guide the side surface of the substrate W when the substrate W is seated on the driving guide member 348a.

The guide members 342a and 344a and the driving guide member 348a are disposed to surround the substrate W which is placed on the guide members 342a and 344a and the driving guide member 348a and supported.

The driving unit (not illustrated) may move the driving plate 348 between a first position and a second position. The first position is a position at which the second support part 340a, that is, the guide members 342a and 344a and the driving guide member 348a, support the substrate W, and the second position is a position at which the guide members 342a and 344a and the driving guide member 348a do not support the substrate W. The distance between the guide members 342a and 344a and the driving guide member 348a when the driving plate 348 is in the first position may be closer than the distance between the guide members 342a and 344a and the driving guide member 348a when the driving plate 348 is in the second position.

When the substrate W is adsorbed and supported by the first support part 330, the driving guide member 348a may be located at the second position. When the driving guide member 348a is located in the second position, the guide members 342a and 344a and the driving guide member 348a may be spaced apart from each other so as not to be in contact with the substrate W adsorbed and supported by the first support part 330.

When the driving plate 348 moves forward, the driving guide member 348a may push and fix the substrate W in front ends directions of the first finger 332 and the second finger 334. Although FIG. 12 illustrates that two driving guide members 348a are installed on the driving plate 348, unlike this, only one driving guide member 348a may be installed at the center of the driving plate 348, or three or more driving guide members 348a may be provided to surround the substrate W placed and supported on the driving guide member 348a. In the present exemplary embodiment, since the guide members 342a and 344a are fixed unlike the driving guide member 348a, the guide members 342a and 344a may be referred to as fixed guide members compared to the driving guide members 348a.

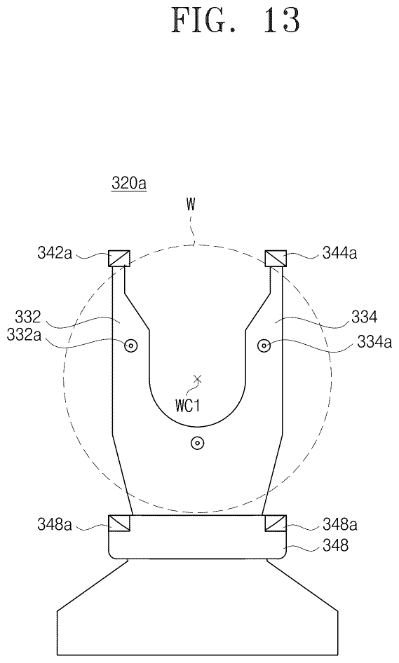

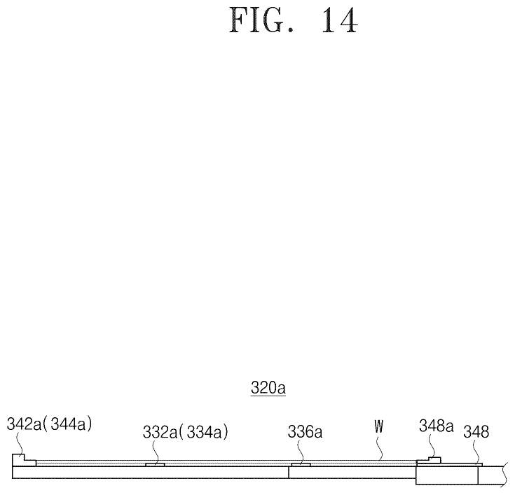

FIGS. 13 and 14 illustrate a state in which the hand of FIG. 12 supports a substrate in the operation of loading the unprocessed substrate of FIG. 7 into the chamber.

FIG. 13 is a front view illustrating a hand 320a of FIG. 12 in the step S10 of loading the unprocessed substrate into the chamber, and FIG. 14 is a side view of the hand 320a of FIG. 13.

Referring to FIGS. 13 and 14, in the step S10 of loading the substrate into the chamber, the substrate W is adsorbed and supported by the first support part 330. When the substrate W is adsorbed and supported by the first support part 330, a driving unit (not illustrated) moves the driving plate 348 to be positioned at the second position. The guide members 342a and 344a and the driving guide member 348a are spaced apart from each other so as not to be in contact with the substrate W adsorbed and supported by the first support part 330. As illustrated in FIGS. 13 and 14, the bottom surface of the substrate W is adsorbed and supported by the vacuum pads 332a, 334a, and 336a, and the substrate W placed on the hand 320a is loaded into the liquid treating chamber 400. For example, the substrate W may be transferred from the buffer chamber 220 to the liquid treating chamber 400.

When the substrate W is loaded into the liquid treating chamber 400, the substrate is processed in the chamber S20.

When the processing of the substrate W is completed in the liquid treating chamber, the step S30 of unloading the processed substrate from the chamber is performed.

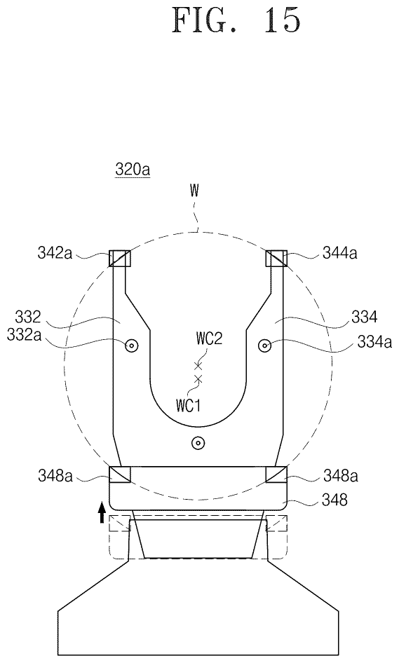

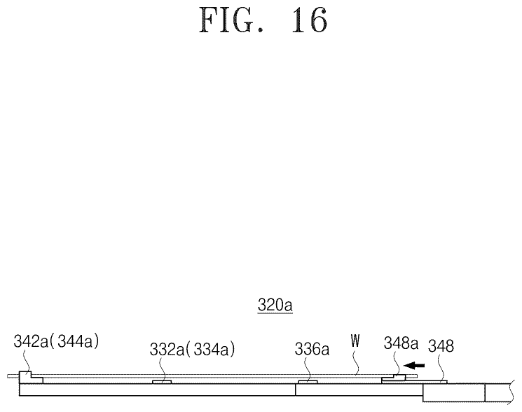

FIGS. 15 and 16 illustrate a state in which the hand of FIG. 12 supports the substrate in the operation of unloading the processed substrate of FIG. 7 from the chamber.

FIG. 15 is a front view illustrating the hand 320a of FIG. 12 in the step S30 of unloading the processed substrate from the chamber, and FIG. 16 is a side view of the hand 320a of FIG. 15.

Referring to FIGS. 15 and 16, in the step S30 of unloading the substrate from the chamber, the substrate W is gripped and supported by the second support part 340a. The driving plate 348 is moved forward by the driving unit (not illustrated), and the substrate W is seated on the guide members 342a and 342b and the driving guide member 348a. That is, the guide members 342a and 342b and the driving guide member 348a support the bottom surface of the side end portion of the substrate W and guide the side surface of the substrate so that the substrate W is fixed on the second support part 340a in a supported state. The driving guide member 348a may push the substrate W in the front end direction of the first finger 332 and the second finger 334 so that the substrate W is fixed by the guide members 342a and 342b and the driving guide member 348a.

According to the exemplary embodiments of FIGS. 12 to 16, as illustrated in FIGS. 13 and 15, a central position WC1 of the substrate W when the first support part 330 supports the substrate W and a central position WC2 of the substrate W when the second support part 340a supports the substrate W are provided differently from each other. When the substrate W is supported by the second support part 340a, the driving plate 348 is moved forward by the driving unit (not illustrated), and since the substrate W is seated on the guide members 342a and 342b and the driving guide member 348a, the central position WC2 of the substrate W when the second support part 340a supports the substrate W is located closer to the front ends of the first finger 332 and the second finger 334 than the central position WC1 of the substrate W when the first support part 330 supports the substrate W.

The substrate W placed on the hand 320 is unloaded from the liquid treating chamber 400. Thereafter, the transfer robot 300 may transfer the substrate W to the buffer chamber 220.

Unlike the hand 320a of FIG. 3, the hand 320a of FIG. 12 described above may make the substrate W be supported by the first support part 330 or the second support part 340a selectively in a manner of moving the driving guide member 348a forward and backward.

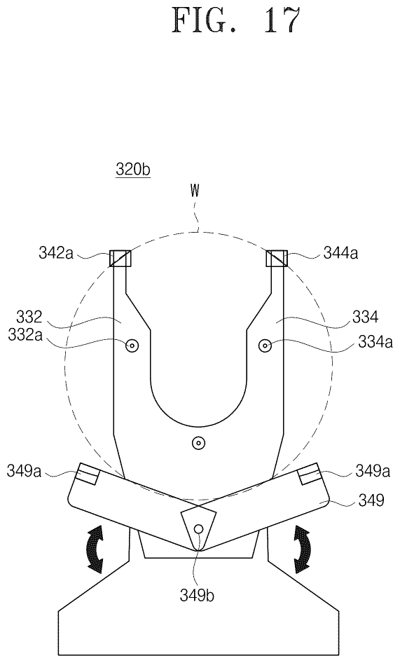

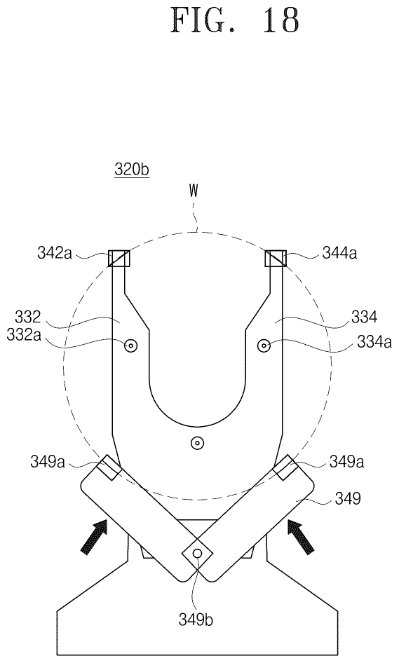

FIGS. 17 to 18 illustrate a hand according to another exemplary embodiment of the present invention. Unlike the hand 320a of FIG. 12, a hand 320b illustrated in FIGS. 17 and 18 may selectively support the substrate W by the first support part 330 or the second support part 340a because the driving unit (not illustrated) rotates and moves the driving plate 349 and accordingly the driving guide member 349a moves forward or backward.

The transfer robot 300 according to the exemplary embodiments of the present invention supports and transfers the substrate W before being processed in the process chamber 260 and the substrate W processed in the process chamber 260 to the different support parts 330 and 340 provided in one hand 320.

Since the first support part 330 and the second support part 340 support the substrate W at different heights, when the substrate W is supported by any one of the first support part 330 and the second support part 340, the other support part is not in contact with the substrate W. Accordingly, impurities, such as particles or fume, of the contaminated (dirty) substrate W may be prevented from contaminating the cleaned (clean) substrate W during the transfer process of the substrate W by the transfer robot 300.

The transfer robot 300 according to the exemplary embodiments of the present invention may transfer the contaminated (dirty) substrate W before processing and the cleaned substrate W with one hand 320. Therefore, compared to the case of transferring the substrate W before and after processing through different hands, the configuration of the return robot 300 may be simplified, the height of the transfer robot 300 may be reduced, and the weight of the transfer robot 300 may be reduced.

In the substrate processing method according to the above-described exemplary embodiment, the present invention has been described based on the case where the operations of loading the unprocessed substrate into the chamber (S10), processing the substrate in the chamber (S20), and unloading the processed substrate from the chamber (S30) are performed in the process chamber 260, especially the liquid treating chamber 400 for liquid treating the substrate W as an example.

However, unlike this, the process chamber 260 may be a drying chamber for drying the substrate W, or may further include a drying chamber in addition to the liquid treating chamber 400. The drying chamber may be a supercritical chamber drying a substrate using a supercritical fluid.

In the above-described exemplary embodiment, it has been illustrated and described that the transfer robot 300 is provided in the transfer frame 240 and transfers the substrate W between the buffer chamber 220 and the process chamber 260. However, unlike this, the configuration of the above-described transfer robot 300 may be identically applied to the index robot 144. That is, the index robot 144 provided in the inside of the index frame 140 may include the first support part 330 and the second support part 340. When the index robot 144 transfers the substrate W between the index module 10 and the buffer chamber 220, the unprocessed substrate W and the processed substrate W may be transferred through different support parts of one hand 320.

Accordingly, impurities, such as particles or fume, of the contaminated (dirty) substrate W may be prevented from contaminating the cleaned (clean) substrate W during the transfer process of the substrate W. Also, the configuration of the transfer robot 300 may be simplified, the height of the transfer robot 300 may be reduced, and the weight of the transfer robot 300 may be reduced.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A transfer robot for transferring a substrate, the transfer robot comprising:
a hand for supporting a substrate; and
a driving unit for driving the hand,
wherein the hand includes:
a base plate;
a first support part mounted on the base plate and vacuum-adsorbing a bottom surface of the substrate and supporting the substrate; and
a second support part mounted on the base plate and supporting an edge region of the substrate, and
the first support part and the second support part are configured to support the substrate at different heights.

2. The transfer robot of claim 1, wherein the second support part includes:
a first support and a second support that support a side end of the substrate and are arranged to face each other with the first support part interposed therebetween when viewed from above; and
a driving unit for moving the first support and the second support in a direction of getting closer to each other or in a direction away from each other.

3. The transfer robot of claim 2, wherein the driving unit moves the first support and the second support between a first position and a second position,
the first position is a position where the first support and the second support support the substrate, and
when viewed from above, the second position is a position where the first support and the second support are spaced apart from the substrate supported by the first support part.

4. The transfer robot of claim 2, wherein the first support and the second support include guide members provided on upper surfaces of the first support and the second support, respectively, and
the guide member supports a side end portion of the substrate and simultaneously guides a side surface of the substrate when the substrate is supported by the second support part.

5. The transfer robot of claim 4, wherein the guide members are provided at front ends and rear ends of the first support and the second support, respectively, and are arranged to surround the substrate when the substrate is supported by the first support part.

6. The transfer robot of claim 2, wherein the driving unit includes:
a driving pulley rotated by a motor;
a driven pulley; and
a belt provided to surround the driving pulley and the driven pulley, and
the first support and the second support are coupled to the belt.

7. The transfer robot of claim 1, further comprising:
a base,
wherein the hand is provided so as to be movable forward and backward with respect to the base.

8. The transfer robot of claim 1, wherein the first support part includes:
a connection part connected to the base plate; and
a first finger and a second finger extending from the connection part, and
each of the first finger, the second finger, and the connection part is provided with a vacuum pad that vacuum-adsorbs the substrate.

9. The transfer robot of claim 1, wherein a plurality of hands is provided, and the plurality of hands is provided to be spaced apart from each other in a vertical direction.

10. The transfer robot of claim 8, wherein the second support part includes:
a fixed guide member provided on an upper surface of the first finger and an upper surface of the second finger;
a driving guide member provided on an upper surface of the connection part; and
a driving unit for moving the driving guide member, and
the fixed guide member and the driving guide member support a side end portion of the substrate and guide a side surface of the substrate when the substrate is supported by the second support part.

11. The transfer robot of claim 10, wherein the driving unit moves the driving guide member between a first position and a second position,
the first position is a position where the driving guide member supports the substrate when the second support part supports the substrate, and
the second position is a position of the driving guide member when the second support part does not support the substrate.

12. The transfer robot of claim 10, wherein when viewed from above, a center position of the substrate when the first support part supports the substrate is provided differently from a center position of the substrate when the second support part supports the substrate.

13.-18. (canceled)

19. A transfer robot for transferring a substrate, the transfer robot comprising:
a hand for supporting a substrate; and
a driving unit for driving the hand,
wherein the hand includes:
a base plate;
a first support part mounted on the base plate and vacuum-adsorbing a bottom surface of the substrate and supporting the substrate; and
a second support part mounted on the base plate and supporting an edge region of the substrate, and
the first support part includes:
a connection part connected to the base plate; and
a first finger and a second finger extending from the connection part, and
each of the first finger, the second finger, and the connection part is provided with a vacuum pad that vacuum-adsorbs the substrate,
the second support part includes:
a first support and a second support that support a side end of the substrate and are arranged to face each other with the first support part interposed therebetween when viewed from above; and
a driving unit for moving the first support and the second support in a direction of getting closer to each other or in a direction away from each other,
the first support and the second support include guide members provided on upper surfaces of the first support and the second support, respectively, and
the guide member supports a side end portion of the substrate and simultaneously guides a side surface of the substrate when the substrate is supported by the second support part, and
the first support part and the second support part are configured to support the substrate at different heights.

20. The transfer robot of claim 19, further comprising:
a base,
wherein a plurality of hands is provided,
the plurality of hands is provided on an upper portion of the base to be spaced apart from each other in a vertical direction, and
each of the plurality of hands is provided so as to be movable forward and backward with respect to the base.
